(19) United States
(12) Patent Application Publication
(10) Pub. No.: US 2003/0222289 A1
(43) Pub. Date: Dec. 4, 2003

(54) Semiconductor device and method of fabricating the same

(75) Inventor: Ryoichi Nakamura, Tokyo (JP)

Correspondence Address: Attn: Norman P. Soloway, HAYES SOLOWAY P.C., 130 W. Cushing Street, Tucson, AZ, 85701, US

(73) Assignee: ELPIDA MEMORY INC.

(21) Appl. No.: 10/447,892

(22) Filed: May 29, 2003

(30) Foreign Application Priority Data
May 30, 2002 (JP) 2002-156605

(51) Int. Cl. H01L 29/80

(52) U.S. Cl. 257/274

(57) ABSTRACT

A semiconductor device includes a PMOS transistor region in which a PMOS transistor is fabricated, an N well diffusion layer region in which an N well diffusion layer is fabricated, a P well diffusion layer region in which a P well diffusion layer is fabricated, and at least one NMOS transistor region in which an NMOS transistor is fabricated, wherein each of the NMOS transistor region and the P well diffusion layer region includes a pocket boron region in which pocket boron is implanted, and a P well is formed across the P well diffusion layer region and the NMOS transistor region such that the P well is electrically connected to the P well diffusion layer region.

### BACKGROUND OF THE INVENTION

1. Field of the Invention

The invention relates to a semiconductor device and a method of fabricating the same, and more particularly to a complementary metal oxide semiconductor (CMOS) transistor and a method of fabricating the same.

2. Description of the Related Art

As problems caused when a metal-insulator-semiconductor field effect transistor (MISFET) is fabricated in a smaller size, there are known hot carrier effect and punch-through.

Hot carrier effect means phenomenon in which channel hot electrons accelerated by a high-intensity electric field generated in a pinch-off region located in the vicinity of a drain region either jump over a barrier formed between a silicon substrate and a surface of a gate oxide film, and resultingly, enter the gate oxide film, or generate electrons in the greater number due to ionization by collision. Hot electrons having entered a gate oxide film cause degradation of characteristics such as variance in a threshold voltage or reduction in mutual conductance. Electrons generated due to ionization by collision turn into a substrate current, resulting in reduction in a break-down voltage in a drain region, or turn into a trigger current for latching up in the case that a transistor is CMOSFET.

As a countermeasure to the above-mentioned hot carrier effect, there is known a lightly-doped drain (LDD) structure in which a lightly doped N⁻ semiconductor area is formed between a drain region and a channel region for relaxing an electric field having a high intensity.

A process for fabricating a metal-insulator-semiconductor field effect transistor (MISFET) having a LDD structure generally includes the steps of implanting impurity ions into a substrate with a gate electrode being used as a mask, to thereby form an N⁻ semiconductor area in the substrate, forming a sidewall spacer comprised of an electrically insulating film, around the gate electrode, and impurity ions are implanted into the substrate with both of the gate electrode and the sidewall spacer being used as a mask, to thereby form N⁺ semiconductor areas (source and drain regions).

In a MISFET fabricated smaller in a size, a depletion layer of a drain region is located closer to a source region with the result of reduction in a height of a voltage barrier around a drain region. Punch-through means phenomenon observed in such a MISFET, in which a current runs between source and drain regions, even if a channel is not formed between the source and drain regions. Punch-through causes problems such as reduction in a break-down voltage in a drain region or an increase in a leakage current.

As one of solutions to the above-mentioned punch-through, there has been suggested a diffusion layer structure which is called “p-pocket”. The suggested “p-pocket” includes a P-type semiconductor area located below source and drain regions for an N-channel type MISFET or an N-type semiconductor area located below source and drain regions for a P-channel type MISFET for suppressing expansion of a depletion layer of the source and drain regions.

A semiconductor integrated circuit is presently required to fabricate both at a smaller temperature in order to fabricate a semiconductor integrated circuit in a smaller size, and in the smaller number of steps in order to reduce fabrication costs.

In order to reduce the number of fabrication steps, a lightly doped drain (LDD) region of an NMOS transistor and a pocket (a punch-through stopper) of a PMOS transistor were concurrently formed in a conventional fabrication process by implanting phosphorous entirely into a substrate without using photolithography.

A conventional fabrication process generally includes a step of annealing a substrate at a high temperature. For instance, in a fabrication process having a step of annealing a substrate at 850 degrees centigrade for about ten seconds after implantation of SD boron into the substrate, the implanted SD boron is diffused more deeply than LDD phosphorous having been implanted entirely into the substrate. As a result, a P well and a P well diffusion layer are electrically connected to each other, causing no problems.

FIG. 1 is a cross-sectional view of a conventional CMOS transistor.

The illustrated CMOS transistor defines four regions, specifically, a first region A in which a PMOS transistor is fabricated, a second region B in which an N well diffusion layer is fabricated, a third region C in which a P well diffusion layer is fabricated, and a fourth region D in which an NMOS transistor is fabricated.

The CMOS transistor illustrated in FIG. 1 includes a gate oxide film 412 formed at a surface of a silicon substrate in the first and fourth regions A and D, a gate polysilicon film 408 formed on the gate oxide film 412, a gate WSi film 409 formed on the gate polysilicon film 408, a LDD sidewall 414 formed on sidewalls of the gate polysilicon film 408 and the gate WSi film 409, a P well 301 formed in the silicon substrate, an N well 302 formed in the silicon substrate, a partition film 303 formed at a surface of the silicon substrate for defining an area in which a device is to be fabricated, a boron region 306 into which boron (B) is implanted and which are formed at a surface of the silicon substrate at opposite sides of the gate oxide film 412 in the second and fourth regions B and D, an arsenic region 307 into which arsenic (As) is implanted and which are formed at a surface of the silicon substrate at opposite sides of the gate oxide film 412 in the second and fourth regions B and D, LDD regions 305 containing phosphorous therein and formed surrounding the boron region 306 and the arsenic region 307, and pocket boron regions 304 formed surrounding the LDD regions 305 in the fourth region D.

FIGS. 2 and 3 illustrate a vertical impurity profile along the broken line C1-C2 in the third region C. FIG. 2 illustrates an impurity profile obtained immediately after implantation of SD boron, and FIG. 3 illustrates an impurity profile obtained when a substrate is annealed at 850 degrees centigrade for 10 seconds after implantation of SD boron.

As is understood in FIG. 2, even in a conventional CMOS transistor, an N-type region composed of LDD phosphorous exists between a P-type region comprised of SD boron existing at a surface of the silicon substrate, and a P-type region comprised of P well boron, immediately after implantation of SD boron into the silicon substrate.

However, as illustrated in FIG. 3, SD boron is thermally diffused due to annealing carried out thereafter, resulting in that the N-type region comprised of LDD phosphorous is canceled by the diffused SD boron.

FIG. 4 is a graph showing a relation between an amount of impurity defined by subtracting a total amount of N-type impurity (LDD phosphorous) from a total amount of P-type impurity (P well boron and SD boron), and a depth measured from a surface of a silicon substrate.

As is understood in view of FIG. 4, a P-type region extends from a surface of a silicon substrate into a deep region.

As having been explained above, since SD boron is broadly diffused by thermal annealing in the conventional CMOS transistor, a P well diffusion layer in the third region C and the P well 301 are electrically connected to each other, ensuring that a voltage can be applied to the P well 301 without any problems.

However, SD boron is never diffused more deeply than the LDD region 305 containing phosphorous therein in a presently used low-temperature process, that is, a process in which thermal annealing is carried out at about 900 degrees centigrade for about 10 seconds after implantation of SD boron.

FIG. 5 illustrates an impurity profile obtained when rapid thermal annealing (RTA) is carried out at 900 degrees centigrade for about 10 seconds after implantation of SD boron. FIG. 6 is a graph showing a relation between an amount of impurity defined by subtracting a total amount of N-type impurity (LDD phosphorous) from a total amount of P-type impurity (P well boron and SD boron), and a depth measured from a surface of a silicon substrate.

As is understood in view of FIG. 6, an N-type region exists between a first P-type region P1 existing in the vicinity of a surface of a silicon substrate and a second P-type region P2 located deeper that the first P-type region P1. That is, a transistor to which rapid thermal annealing (RTA) is applied at 900 degrees centigrade for about 10 seconds after implantation of SD boron has a P/N/P structure.

In a P/N/P structure, the third region C and the P well 301 are not electrically connected to each other. This results in that it is not possible to feed a current to the P well 301 from an external circuit, causing instability in operation of the transistor and defects such as latch-up.

A simplest solution to avoid electrical isolation between the third region C and the P well 301 is a process including steps of forming an opening with a resist only for the third region C by means of photolithography and etching, and implanting boron into a substrate with the resist being used as a mask to thereby turn the N-type region existing between the third region C and the P well 301, into a P-type region.

However, this process is accompanied with problems of an increase in the number of fabrication steps and an increase in fabrication costs.

Japanese Patent Application Publication No. 9-213809 has suggested a method of fabricating a transistor which method is capable of avoiding the above-mentioned hot carrier effect and punch-through.

Hereinbelow is explained the suggested method.

FIG. 7 is a plan view of a unit cell of a CMOS gate array fabricated in accordance with the method, and FIG. 8 is a cross-sectional view of the unit cell illustrated in FIG. 7.

A semiconductor substrate 601 is composed of P-type monocrystal silicon. A P-type well 602 and an N-type well 603 are formed adjacent to each other on a surface of the semiconductor region 601 in a region in which a unit cell is to be arranged. On the P-type well 602 is formed a gate electrode 604A of an N-channel MISFET constituting a part of the unit cell, and on the N-type well 603 is formed a gate electrode 604B of a P-channel MISFET constituting a part of the unit cell.

Adjacent to a region 600A in which the N-channel MISFET is fabricated is formed a P-type well region 606 through which a predetermined constant voltage is applied to the P-type well 602. Adjacent to a region 600B in which the P-channel MISFET is fabricated is formed an N-type well region 607 through which a predetermined constant voltage is applied to the N-type well 603.

The region 600A in which the N-channel MISFET is fabricated, the P-type well region 606, the region 600B in which the P-channel MISFET is fabricated, and the N-type well region 607 are electrically insulated from one another by a field oxide film 608.

Hereinbelow is explained a method of fabricating the N-channel MISFET having a LDD structure and the P-channel MISFET having a pocket structure.

As illustrated in FIGS. 9 and 10, the region 600B and the N-type well region 607 are covered with a photoresist 620. Then, an N-type impurity (P) and a P-type impurity (B) are implanted in turn into the P-type well 602 by oblique ion-implantation process to thereby form an N-type semiconductor region 609A and a P-type semiconductor region (pocket) 610A around the gate electrode 604A in the P-type well 602. The N-type and P-type impurities are implanted also into the P-type well 602 in the P-type well region 606, resulting in that an N-type semiconductor region 609B and a P-type semiconductor region 610B are formed at a surface of the semiconductor substrate 610 in the P-type well region 606.

After removal of the photoresist 620, as illustrated in FIGS. 11 and 12, the region 600A and the P-type well region 606 are covered with a photoresist 621. Then, a P-type impurity (BF₂) and an N-type impurity (P) are implanted in turn into the N-type well 603 to thereby form a P-type semiconductor region 611A and an N-type semiconductor region (pocket) 612A around the gate electrode 604B in the N-type well 603. The N-type and P-type impurities are implanted also into the N-type well 603 in the N-type well region 607, resulting in that a P-type semiconductor region 611B and an N-type semiconductor region (pocket) 612B are formed at a surface of the semiconductor substrate 610 in the N-type well 603 in the N-type well region 607.

After removal of the photoresist 621, as illustrated in FIGS. 13 and 14, sidewall spacers 615 are formed on sidewalls of the gate electrodes 604A and 604B. The sidewall spacers 615 are comprised of silicon dioxide.

Then, the N-type well 603 in the region 600B and the P-type well 602 in the P-type well region 606 are covered at a surface thereof with a photoresist 622. Then, an N-type impurity (As) is implanted into the P-type well 602 in the region 600A and the N-type well 603 in the N-type well region 607 to thereby form a first N+ semiconductor region 613A and a second N+ semiconductor region 613B. The first N+ semiconductor region 613A acts as source and drain regions of the N-channel MISFET, and the second N+ semiconductor region 613B acts as a region through which a voltage is applied to the N-type well 603.

Then, after removal of the photoresist 622, as illustrated in FIGS. 15 and 16, the P-type well 602 in the region 60A and the N-type well 603 in the N-type well region 607 are covered at a surface thereof with a photoresist 623. Then, a P-type impurity (BF₂) is implanted into the N-type well 603 in the region 600B and the P-type well 602 in the P-type well region 606 to thereby form a first P+ semiconductor region 614A and a second P+ semiconductor region 614B. The first P+ semiconductor region 614A acts as source and drain regions of the P-channel MISFET, and the second P+ semiconductor region 614B acts as a region through which a voltage is applied to the P-type well 602.

Thus, there are formed the N-channel MISFET having a LDD structure and the P-channel MISFET having a pocket structure.

However, the CMOS transistor illustrated in FIGS. 1 to 6 and the method of fabricating a transistor, having been explained with reference to FIGS. 7 to 16 are accompanied with a problem that an additional step of implanting pocket boron for NMOS transistor has to be carried out in order to ensure electrical connection between a P-type well and a region in which a P-type well diffusion layer is fabricated.

Japanese Patent Application Publication No. 2000-68388 has suggested a method of fabricating a semiconductor device which method makes it possible to form a LDD region, a pocket region, a source region and a drain region by carrying out photolithography steps four times.

Japanese Patent Application Publication No. 2002-43436 has suggested a method of fabricating a semiconductor device including a first MOSFET having a channel having a first electrical conductivity, and a second MOSFET having a channel having a second electrical conductivity. The method includes steps of forming an N⁻ layer by ion implantation with gate electrodes being used as a mask, covering a region in which the first MOSFET is fabricated, with a resist, implanting ion into a semiconductor substrate to turn the N⁻ layer into a P⁻ layer, forming an N⁻ pocket layer by ion implantation through the use of a resist as a mask, forming sidewalls around the gate electrodes, and forming source and drain by alternately implanting P-type and N-type impurities into a semiconductor substrate.

### SUMMARY OF THE INVENTION

In view of the above-mentioned problem in the conventional semiconductor device and a method of fabricating the same, it is an object of the present invention to provide a semiconductor device and a method of fabricating the same both of which are capable of ensuring electrical connection between a P-type well and a region in which a P-type well diffusion layer is fabricated, without carrying out an additional step.

In one aspect of the present invention, there is provided a semiconductor device including a PMOS transistor region in which a PMOS transistor is fabricated, an N well diffusion layer region in which an N well diffusion layer is fabricated, a P well diffusion layer region in which a P well diffusion layer is fabricated, and an NMOS transistor region in which an NMOS transistor is fabricated, wherein each of the NMOS transistor region and the P well diffusion layer region includes a P-type impurity region in which a P-type impurity is implanted, and a P well is formed across the P well diffusion layer region and the NMOS transistor region such that the P well is electrically connected to the P well diffusion layer region.

For instance, the P-type impurity is preferably pocket boron.

For instance, the semiconductor device may include a plurality of NMOS transistor regions in each of which an NMOS transistor is fabricated.

It is preferable that NMOS transistors to be fabricated in the NMOS transistor regions have source and drains structurally different from one another.

For instance, the semiconductor device may include two NMOS transistor regions in which low-voltage and high-voltage NMOS transistors are fabricated.

For instance, the NMOS transistor region may be comprised of a first region in which a peripheral transistor is fabricated and a second region in which a cell transistor is fabricated.

In another aspect of the present invention, there is provided a method of fabricating a semiconductor device including a PMOS transistor region in which a PMOS transistor is fabricated, an N well diffusion layer region in which an N well diffusion layer is fabricated, a P well diffusion layer region in which a P well diffusion layer is fabricated, and at least one NMOS transistor region in which an NMOS transistor is fabricated, the method including the steps of (a) implanting N-type impurity into a substrate to concurrently form a lightly doped drain (LDD) region of the NMOS transistor and a pocket region of the PMOS transistor area, and (b) implanting a P-type impurity into the NMOS transistor region and the P well diffusion layer region to electrically connect a P well formed across the P well diffusion layer region and the NMOS transistor region, to the P well diffusion layer region.

For instance, the P-type impurity is preferably pocket boron.

It is preferable that an N-type impurity as well as the P-type impurity is implanted into the P well diffusion layer region in the step (b) to form a LDD region.

For instance, the N-type impurity is preferably arsenic.

The advantages obtained by the aforementioned present invention will be described hereinbelow.

In accordance with the present invention, a step of implanting pocket boron for an NMOS transistor, which step is carried out for another purpose, specifically, for the purpose of suppression of short channel effect, is carried out further to a region in which a P-type well diffusion layer is fabricated. Thus, it would be possible to turn an N-type region existing between a P-type well and a P-type well diffusion layer region, into a P-type region. Thus, electrical connection can be ensured between a P-type well and a P-type well diffusion layer region at the smaller number of steps than the same in the conventional method, even in a process including a step of carrying out thermal annealing at a relatively low temperature.

The present invention is superior to the method of fabricating a transistor, suggested in the above-mentioned Japanese Patent Application Publication No. 9-213809.

In the method suggested in the Publication, the following steps are carried out for electrically connecting a well and a region through which a voltage is applied to the well, to each other.

(a) A resist pattern is formed by photolithography. The resist pattern has an opening through which an NMOS transistor region and a P well diffusion layer region are exposed. Firstly a P-type impurity and secondly an N-type impurity in ions are implanted into a silicon substrate with the resist pattern being used as a mask, to thereby form a pocket region and a LDD region.

(b) A resist pattern is formed by photolithography. The resist pattern has an opening through which a PMOS transistor region and an N well diffusion layer region are exposed. Firstly an N-type impurity and secondly a P-type impurity in ions are implanted into a silicon substrate with the resist pattern being used as a mask, to thereby form a pocket region and a LDD region.

(c) There is formed a resist pattern having an opening through which an N⁺ region and an N well diffusion layer region are exposed. An N-type SD impurity is implanted into a silicon substrate more deeply than a P-type LDD region with the resist pattern being used as a mask.

(d) There is formed a resist pattern having an opening through which a P⁺ region and a P well diffusion layer region are exposed. A P-type SD impurity is implanted into a silicon substrate more deeply than an N-type LDD region with the resist pattern being used as a mask.

In accordance with the present invention, the following steps are carried out for electrically connecting a well and a region through which a voltage is applied to the well, to each other.

(A) An N-type impurity is implanted entirely into a silicon substrate to thereby form a pocket region in a PMOS transistor region and a LDD region in an NMOS transistor region.

(B) A resist pattern is formed by photolithography. The resist pattern has an opening through which an NMOS transistor region and a P well diffusion layer region are exposed. Then, a P-type impurity is implanted into a silicon substrate with the resist pattern being used as a mask to thereby cancel the N-type impurity having been implanted into the P well diffusion layer region in the above-mentioned step (A).

(C) There is formed a resist pattern having an opening through which an N⁺ region and an N well diffusion layer region are exposed. An N-type SD impurity is implanted into a silicon substrate with the resist pattern being used as a mask.

(D) There is formed a resist pattern having an opening through which a P⁺ region and a P well diffusion layer region are exposed. A P-type SD impurity is implanted into a silicon substrate with the resist pattern being used as a mask.

In accordance with the present invention, it is not necessary to carry out photolithography in the step (A) unlike the method suggested in the above-mentioned Publication. This is based on the fact that a problem of hot carriers exerts less harmful influence on a PMOS transistor than on an NMOS transistor. That is, only pocket boron is implanted into a silicon substrate in a PMOS transistor, but phosphorus is not implanted into a LDD region in a PMOS transistor. Thus, the present invention makes it possible to fabricate a transistor having the same functions as those of a transistor fabricated in accordance with the conventional method suggested in the above-mentioned Publication, in the smaller number of steps and in lower fabrication costs than those in the conventional method.

Since an N-type impurity having been implanted into a P well diffusion layer region is cancelled by a P-type impurity implanted into a pocket region, it is no longer necessary to implant a P-type SD impurity into a silicon substrate more deeply than an N-type LDD region.

As explained in the later-mentioned second embodiment, even if two NMOS transistors, specifically, low-voltage and high-voltage NMOS transistors are to be fabricated, it would be possible to fabricate such two NMOS transistors, keeping a P well diffusion layer and a P well in electrical connection with each other, without an increase in the number of fabrication steps, by implanting an N-type impurity entirely into a silicon substrate, and implanting a P-type impurity only into a P well diffusion layer region and a low-voltage NMOS region by means of photolithography.

Even in fabrication of an integrated circuit having two or more NMOS transistors, such as DRAM, the present invention can reduce the number of fabrication steps and fabrication costs in comparison with the method suggested in the above-mentioned Publication.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a cross-sectional view of a conventional semiconductor device.

FIG. 2 illustrates an impurity profile of the conventional semiconductor device illustrated in FIG. 1.

FIG. 3 illustrates an impurity profile of the conventional semiconductor device illustrated in FIG. 1.

FIG. 4 illustrates an impurity profile of the conventional semiconductor device illustrated in FIG. 1.

FIG. 5 illustrates an impurity profile of the conventional semiconductor device illustrated in FIG. 1.

FIG. 6 illustrates an impurity profile of the conventional semiconductor device illustrated in FIG. 1.

FIG. 7 is a plan view of another conventional semiconductor device, illustrating a step in a method of fabricating the same.

FIG. 8 is a cross-sectional view of another conventional semiconductor device, illustrating a step in a method of fabricating the same.

FIG. 9 is a plan view of another conventional semiconductor device, illustrating a step in a method of fabricating the same.

FIG. 10 is a cross-sectional view of another conventional semiconductor device, illustrating a step in a method of fabricating the same.

FIG. 11 is a plan view of another conventional semiconductor device, illustrating a step in a method of fabricating the same.

FIG. 12 is a cross-sectional view of another conventional semiconductor device, illustrating a step in a method of fabricating the same.

FIG. 13 is a plan view of another conventional semiconductor device, illustrating a step in a method of fabricating the same.

FIG. 14 is a cross-sectional view of another conventional semiconductor device, illustrating a step in a method of fabricating the same.

FIG. 15 is a plan view of another conventional semiconductor device, illustrating a step in a method of fabricating the same.

FIG. 16 is a cross-sectional view of another conventional semiconductor device, illustrating a step in a method of fabricating the same.

FIG. 17 is a cross-sectional view of a semiconductor device in accordance with the first embodiment of the present invention.

FIG. 18 illustrates an impurity profile of the semiconductor device illustrated in FIG. 17.

FIG. 18 is a cross-sectional view of the semiconductor device in accordance with the first embodiment of the present invention, illustrating respective step in a method of fabricating the same.

FIG. 19 is a cross-sectional view of the semiconductor device in accordance with the first embodiment of the present invention, illustrating respective step in a method of fabricating the same.

FIG. 20 is a cross-sectional view of the semiconductor device in accordance with the first embodiment of the present invention, illustrating respective step in a method of fabricating the same.

FIG. 21 is a cross-sectional view of the semiconductor device in accordance with the first embodiment of the present invention, illustrating respective step in a method of fabricating the same.

FIG. 22 is a cross-sectional view of the semiconductor device in accordance with the first embodiment of the present invention, illustrating respective step in a method of fabricating the same.

FIG. 23 is a cross-sectional view of the semiconductor device in accordance with the first embodiment of the present invention, illustrating respective step in a method of fabricating the same.

FIG. 24 is a cross-sectional view of the semiconductor device in accordance with the first embodiment of the present invention, illustrating respective step in a method of fabricating the same.

FIG. 25 is a cross-sectional view of the semiconductor device in accordance with the first embodiment of the present invention, illustrating respective step in a method of fabricating the same.

FIG. 26 illustrates an impurity profile of the semiconductor device in accordance with the first embodiment of the present invention.

FIG. 27 is a cross-sectional view of the semiconductor device in accordance with the second embodiment of the present invention, illustrating a step in a method of fabricating the same.

FIG. 28 is a cross-sectional view of the semiconductor device in accordance with the second embodiment of the present invention.

FIG. 29 illustrates an impurity profile of the semiconductor device in accordance with the second embodiment of the present invention.

FIG. 30 illustrates an impurity profile of the semiconductor device in accordance with the second embodiment of the present invention.

FIG. 31 is a cross-sectional view of the semiconductor device in accordance with the third embodiment of the present invention.

FIG. 32 is a cross-sectional view of the semiconductor device in accordance with the third embodiment of the present invention.

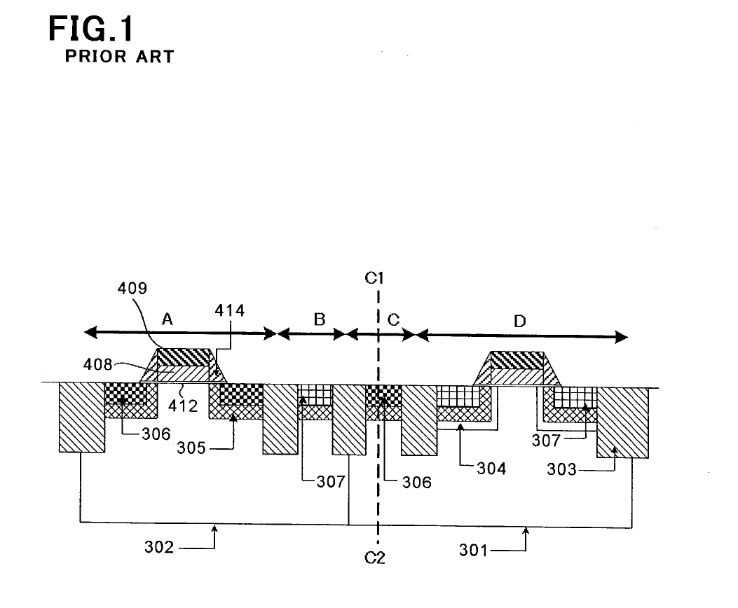

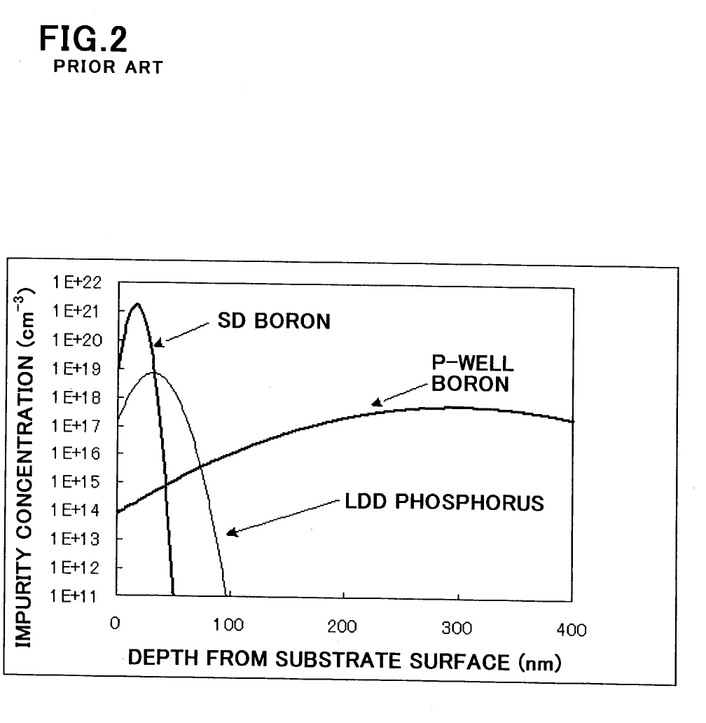

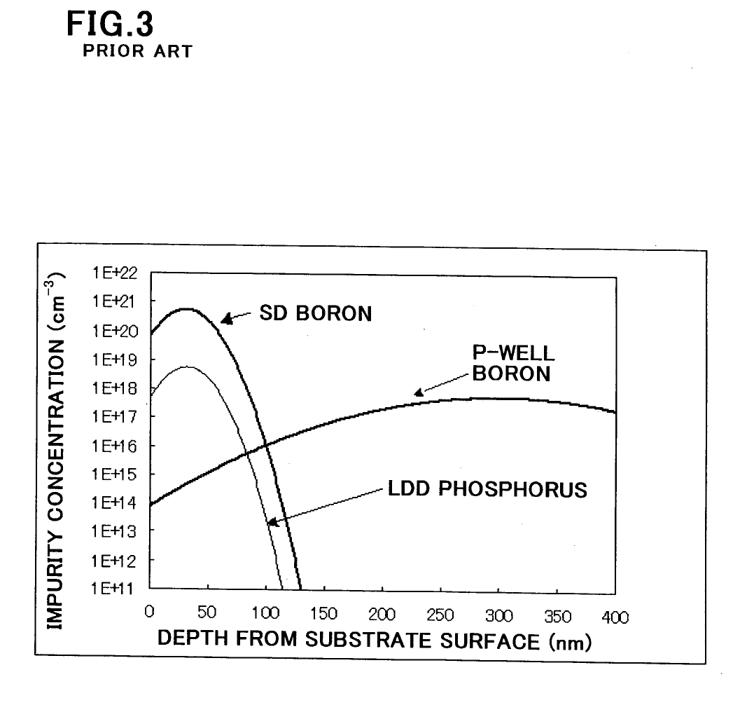

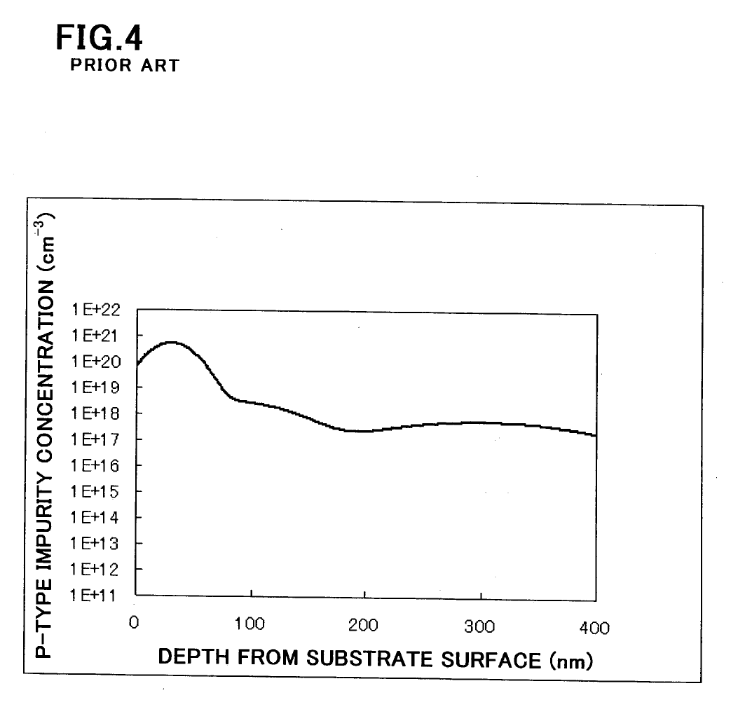

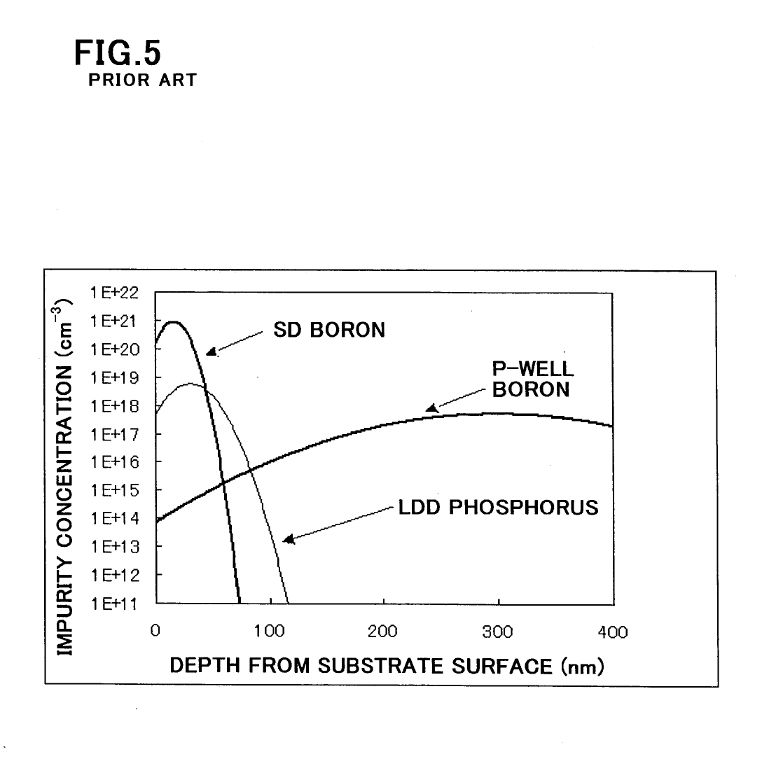

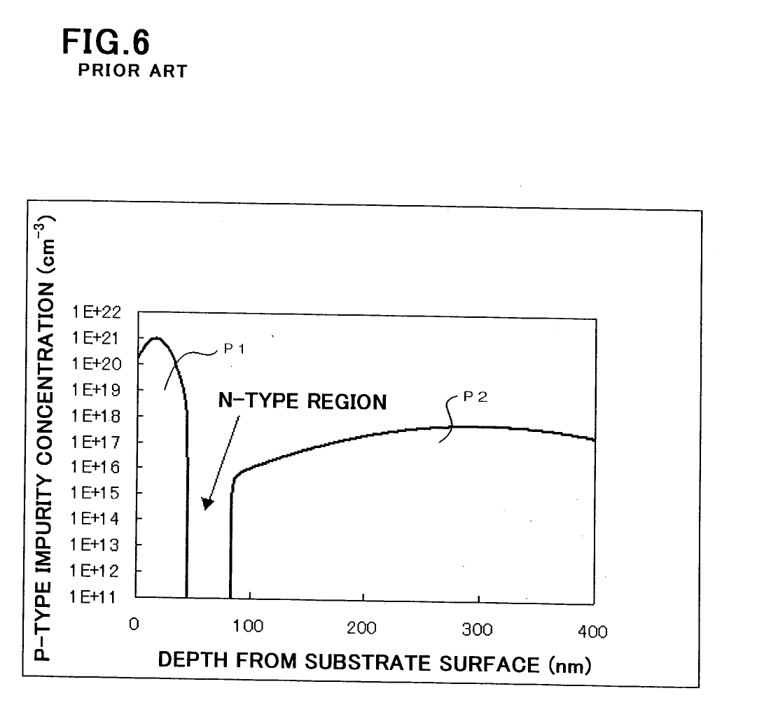

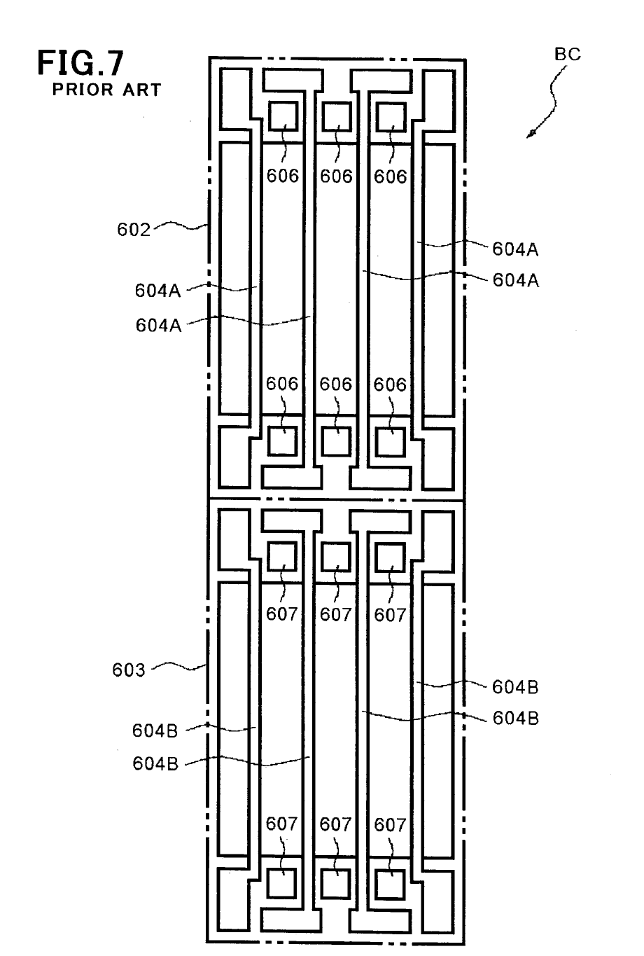

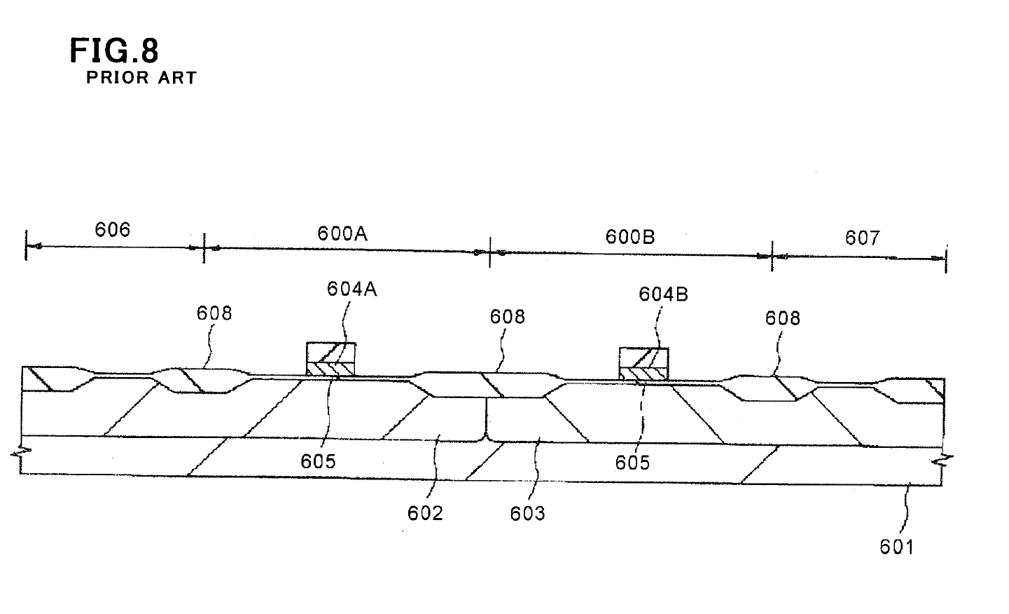

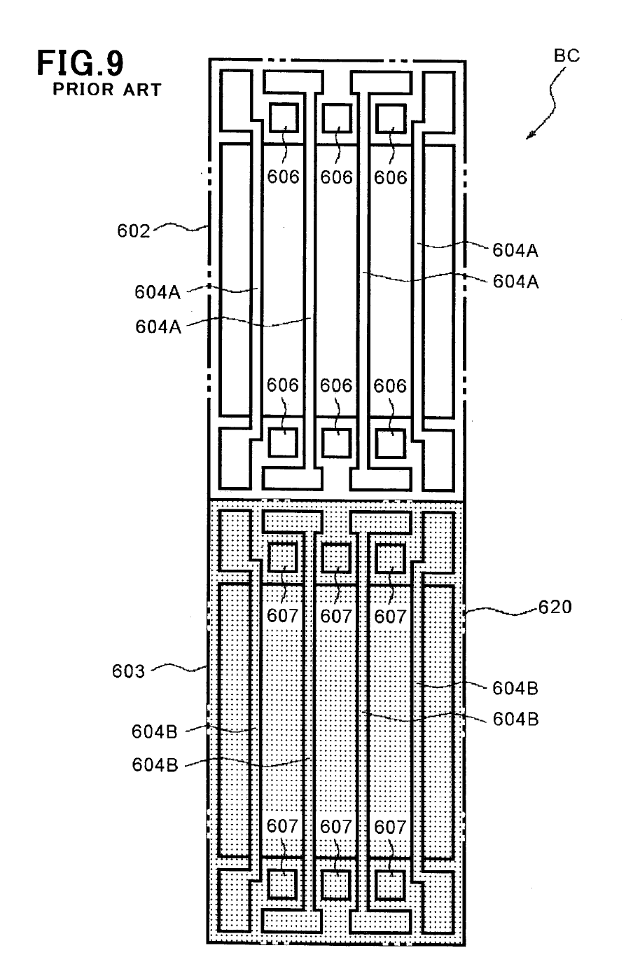

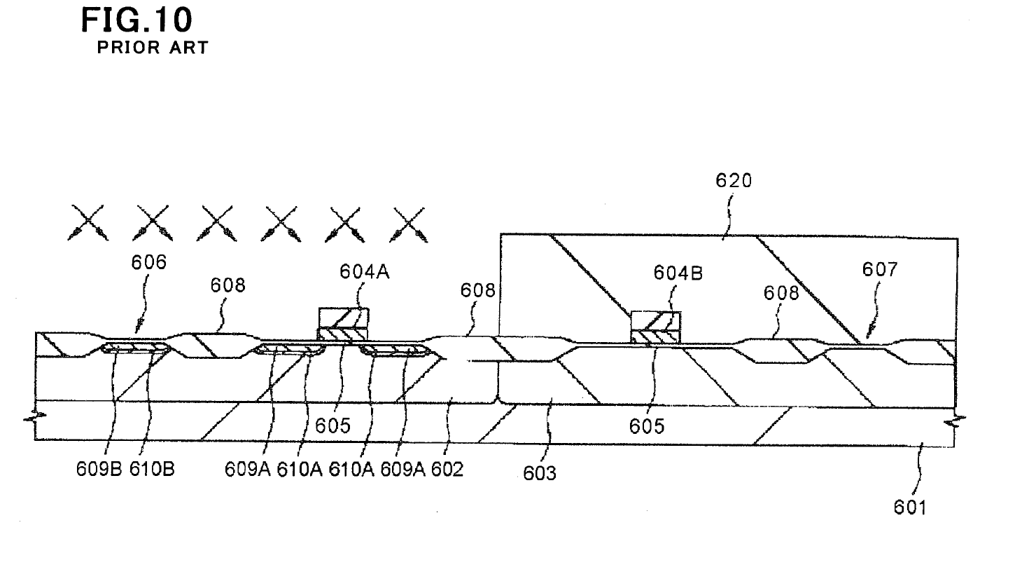

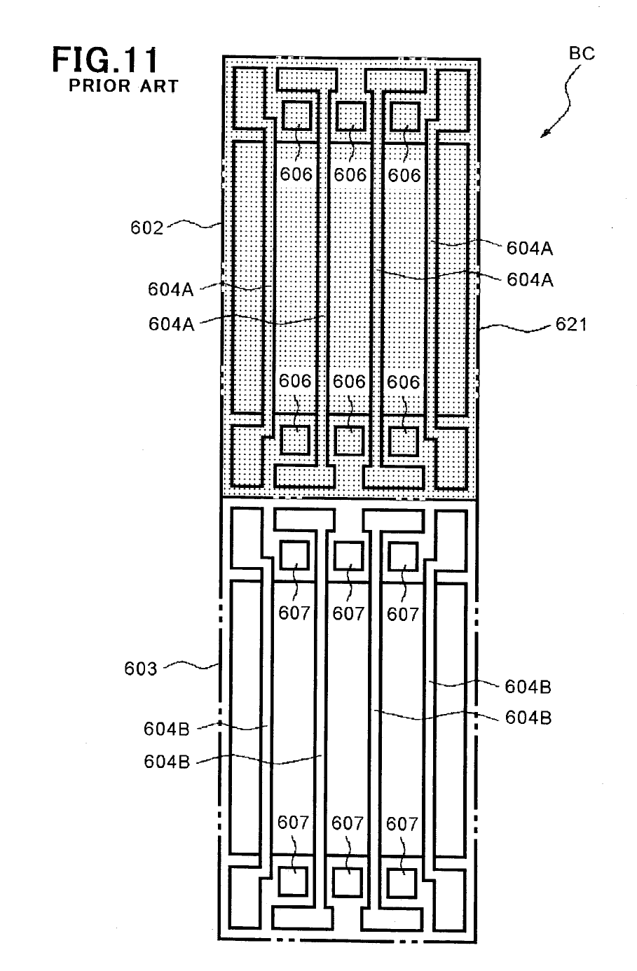

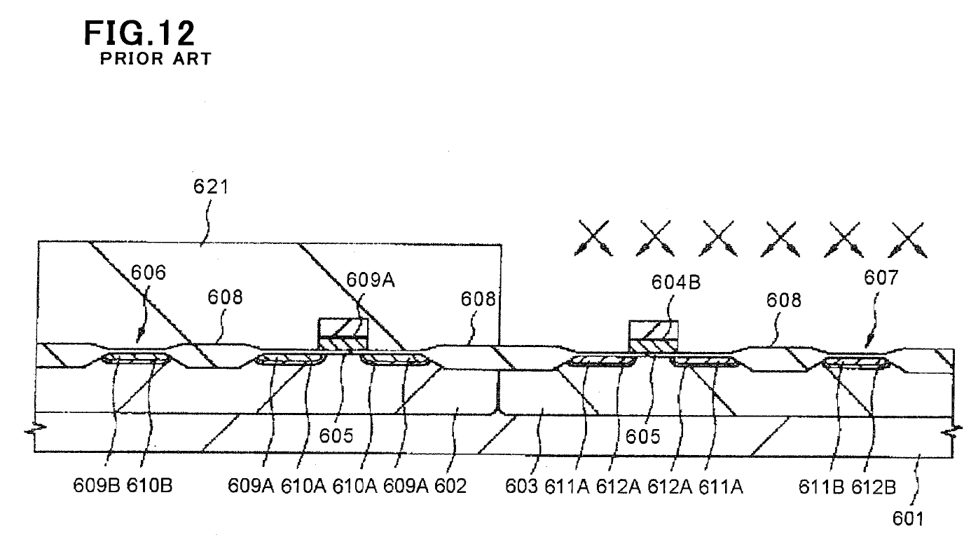

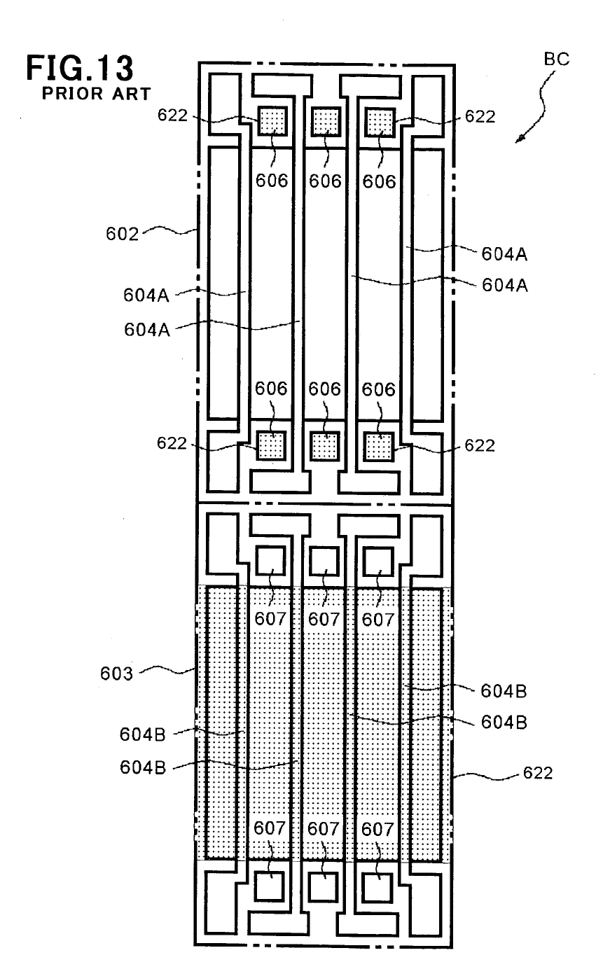

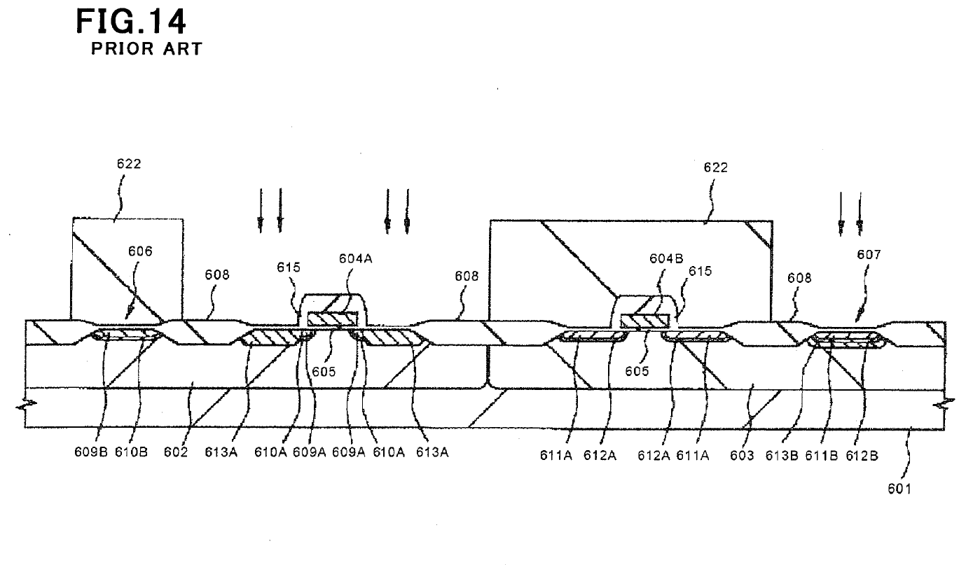

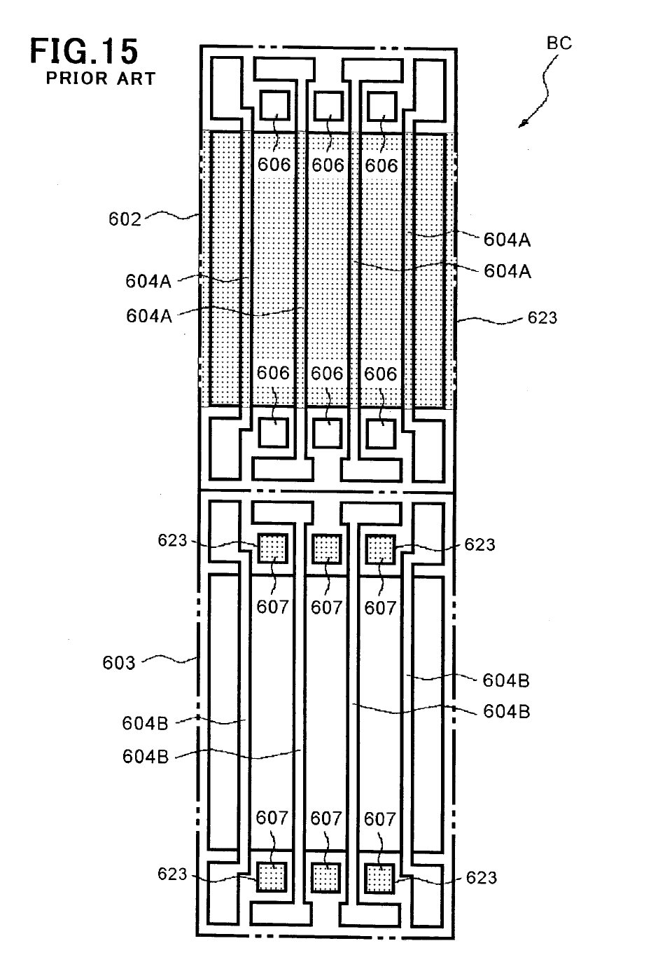

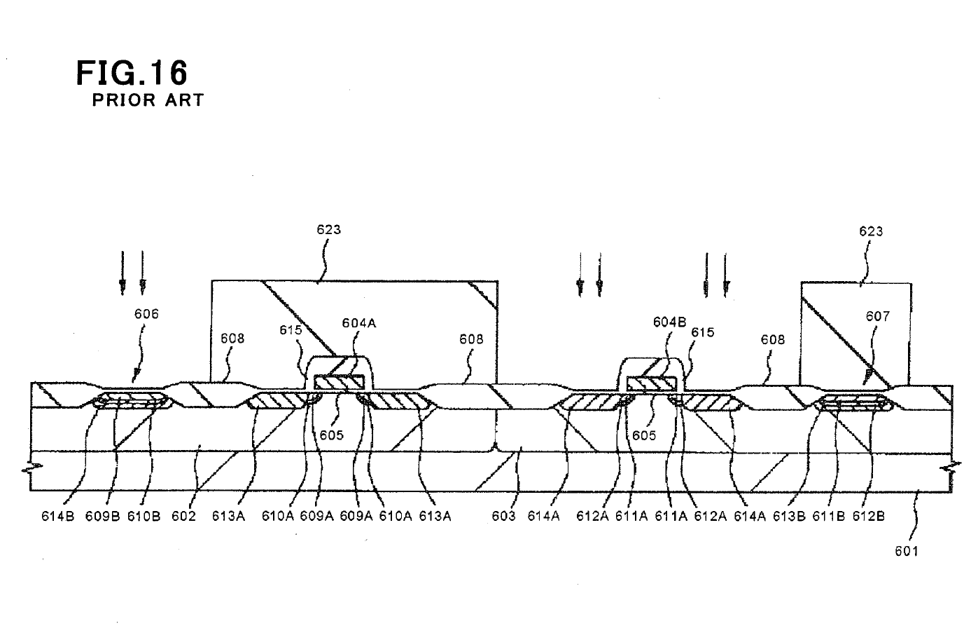

### DESCRIPTION OF THE PREFERRED EMBODIMENTS

Preferred embodiments in accordance with the present invention will be explained hereinbelow with reference to drawings.

[First Embodiment]

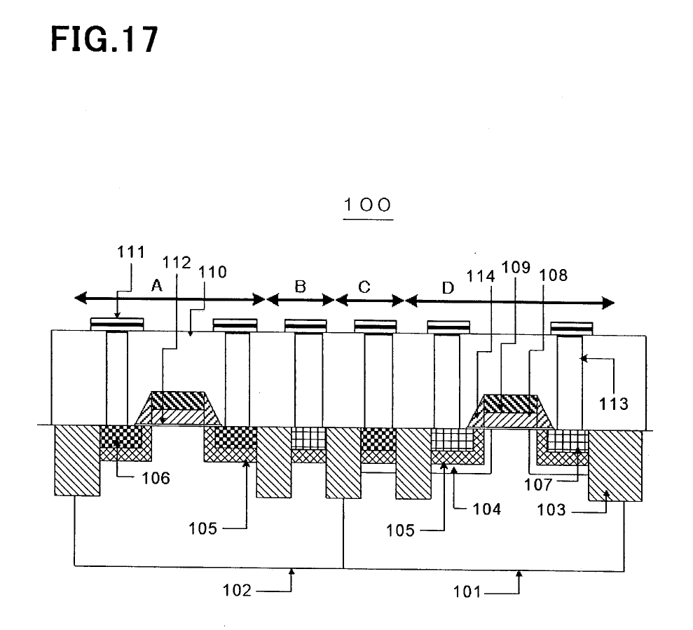

FIG. 17 is a cross-sectional view of a semiconductor device in accordance with the first embodiment of the present invention.

A semiconductor device in accordance with the first embodiment is fabricated as a CMOS transistor 100.

The CMOS transistor 100 in accordance with the first embodiment has four regions, specifically, a PMOS transistor region A in which a PMOS transistor is fabricated, an N well diffusion layer region B through which a voltage is applied to a later-mentioned N well, a P well diffusion layer region C through which a voltage is applied to a later-mentioned P well, and an NMOS transistor region D in which an NMOS transistor is fabricated.

A predetermined voltage is applied to N and P wells through the N and P well diffusion layer regions B and C from an external voltage source in order to keep voltages at the N and P wells stable.

As illustrated in FIG. 17, the CMOS transistor 100 includes a gate oxide film 112 formed at a surface of a silicon substrate in the PMOS transistor region A and the NMOS transistor region D, a gate polysilicon film 108 formed on the gate oxide film 112, a gate WSi film 109 formed on the gate polysilicon film 108, a LDD sidewall 114 formed on sidewalls of the gate polysilicon film 108 and the gate WSi film 109, a P well 101 formed in the silicon substrate in the P well diffusion layer region C and the NMOS transistor region D, an N well 102 formed in the silicon substrate in the PMOS transistor region A and the N well diffusion layer region B, a field oxide film 103 formed at a surface of the silicon substrate, a boron region 106 into which boron (B) is implanted and which are formed at a surface of the silicon substrate in the P well diffusion layer region C and further at opposite sides of the gate oxide film 112 in the PMOS transistor region A, an arsenic region 107 into which arsenic (As) is implanted and which are formed at a surface of the silicon substrate in the N well diffusion layer region B and further at opposite sides of the gate oxide film 112 in the NMOS transistor region D, LDD regions 105 containing phosphorous therein and formed surrounding the boron regions 106 and the arsenic region 107, pocket boron regions 104 formed surrounding the LDD regions 105 in the P well diffusion layer region C and the NMOS transistor region D, an interlayer insulating film 110 formed on the silicon substrate, contact plugs 113 formed passing through the interlayer insulating film 110 so as to reach the boron region 106 and the arsenic region 107, and wiring layers 111 formed on the interlayer insulating film 110 so as to make electrical contact with the contact plugs 113.

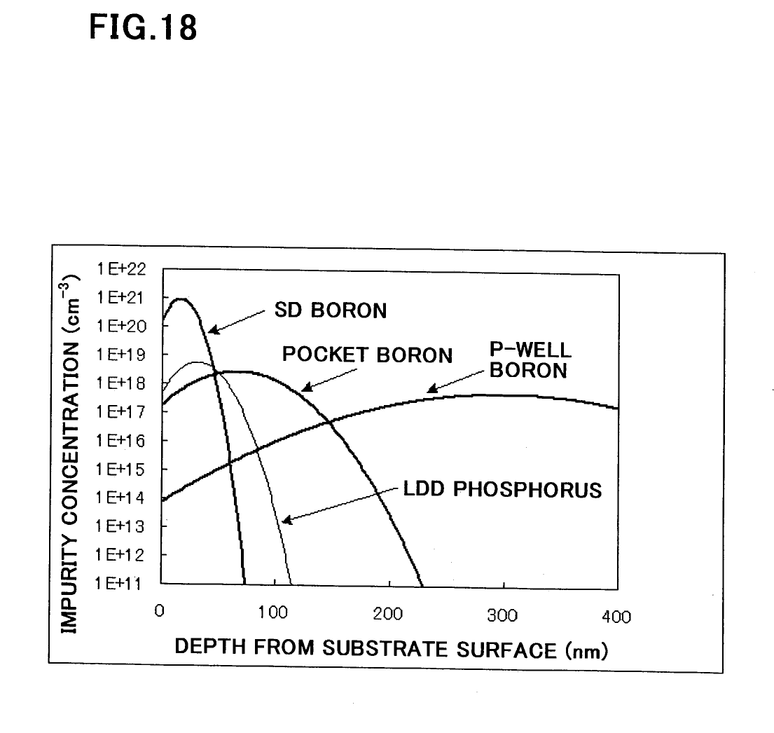

FIG. 18 illustrates an impurity profile in a vertical direction, that is, in a depth-wise direction starting from a surface of the silicon substrate in the P well diffusion layer region C.

Hereinbelow is explained an example of a method of fabricating the CMOS transistor 100 in accordance with the first embodiment.

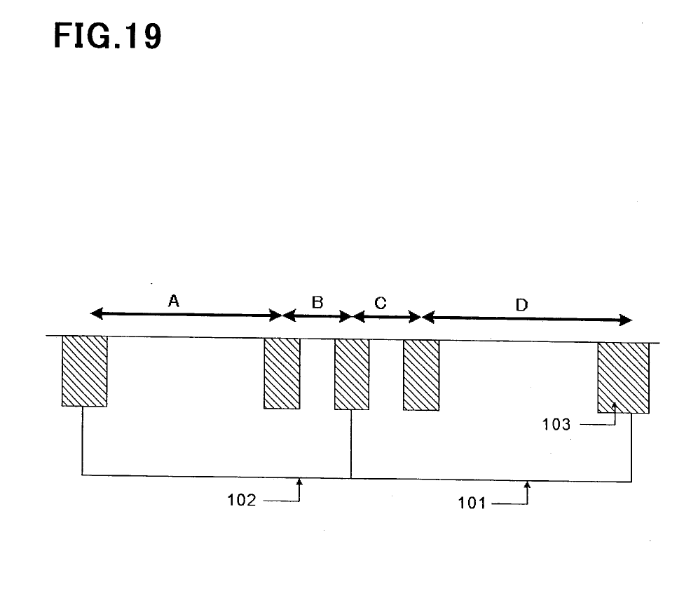

As illustrated in FIG. 19, the field oxide film 103 having a depth of 250 nm is formed at a surface of the silicon substrate for partitioning areas in each of which a device is to be fabricated. Then, impurity ion is implanted into the silicon substrate to thereby form the N well 102 and the P well 101.

For instance, the N well 102 may be formed by carrying out ion implantations twice, that is, the N well 102 may be firstly implanted at 700 keV with doses of 1×10¹³ phosphorus cm² and secondly implanted at 300 keV with doses of 1×10¹³ phosphorus cm². Similarly, the P well 101 may be formed by carrying out ion implantations twice, that is, the P well 101 may be firstly implanted at 300 keV with doses of 1×10¹³ boron cm² and secondly implanted at 100 keV with doses of 1×10¹³ boron cm².

After the ion implantation into the silicon substrate, the silicon substrate is kept in nitrogen atmosphere at 900 degrees centigrade for about 10 minutes for activation of ions. The PMOS transistor region A and the NMOS transistor region D may be additionally implanted at about 10 keV with boron for ensure a desired threshold voltage.

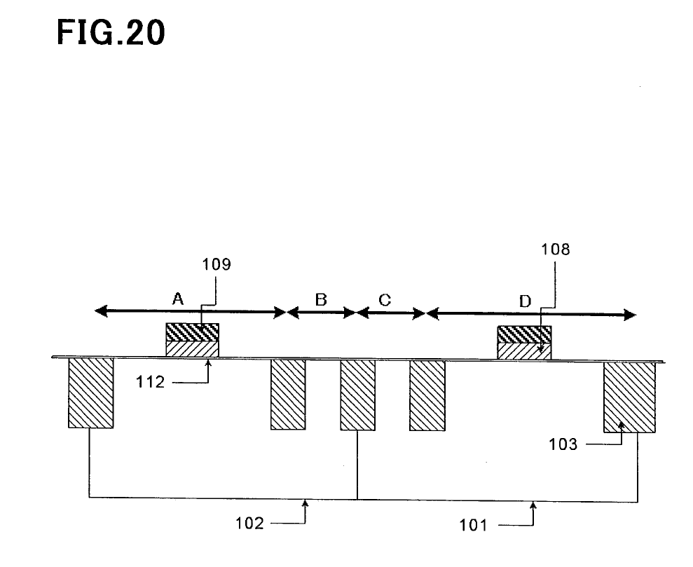

Then, as illustrated in FIG. 20, the gate oxide film 112 having a thickness of about 5.0 nm is formed at a surface of the silicon substrate by thermal oxidation.

Then, polysilicon 108 into which phosphorus is doped at doses of about 2×10²⁰ cm ³ is deposited on the gate oxide film 112 by a thickness of 100 nm by low pressure chemical vapor deposition (LP-CVD), and then, WSi 109 is deposited on the polysilicon by a thickness of 100 nm by LP-CVD. Then, the polysilicon 108 and the WSi 109 are patterned into a gate electrode by photolithography and etching. The resultant gate electrode has a length of 0.20 micrometers, for instance.

Thus, as illustrated in FIG. 20, on the silicon substrate are formed a gate electrode of the PMOS transistor in the PMOS transistor region A and a gate electrode of the NMOS transistor in the NMOS transistor region D.

Then, phosphorus is implanted entirely into the silicon substrate without using photolithography. For instance, the silicon substrate is implanted at 25 keV with doses of 2×10¹³ cm² of phosphorus.

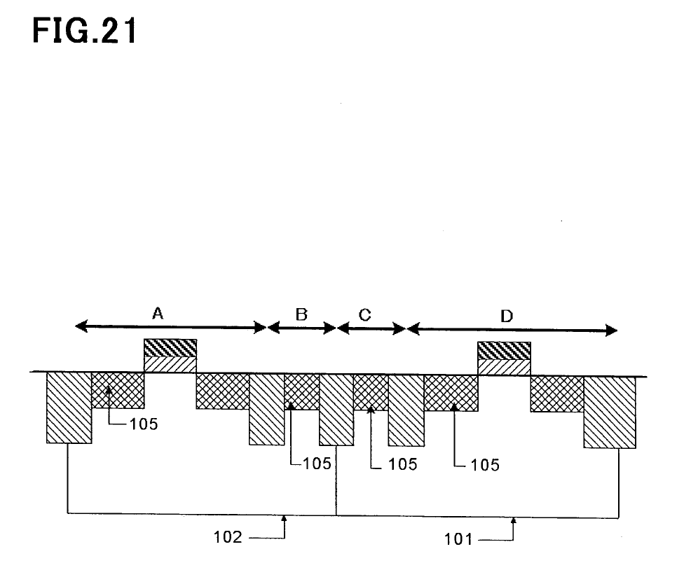

As illustrated in FIG. 21, the LDD region 105 is formed in the NMOS transistor region D as a result of the phosphorus implantation. The LDD region 105 enhances a resistance of the NMOS transistor to hot carriers. The pocket region or punch-through stopper region 105 is also formed in the PMOS transistor region A as a result of the phosphorus implantation. The LDD region 105 suppresses short channel effect of the PMOS transistor.

Since phosphorus was implanted entirely into the silicon substrate, the phosphorus regions 105 are formed at a surface of the silicon substrate also in the N well diffusion layer region B and the P well diffusion layer region C, as illustrated in FIG. 21.

Then, a resist pattern is formed on the silicon substrate by means of photolithography. The resist pattern has an opening through which the P well diffusion layer region C and the NMOS transistor region D are exposed. Then, pocket boron is implanted into the silicon substrate with the resist pattern being used as a mask. For instance, the silicon substrate is implanted at 20 keV with doses of 2×10¹³ cm² of boron.

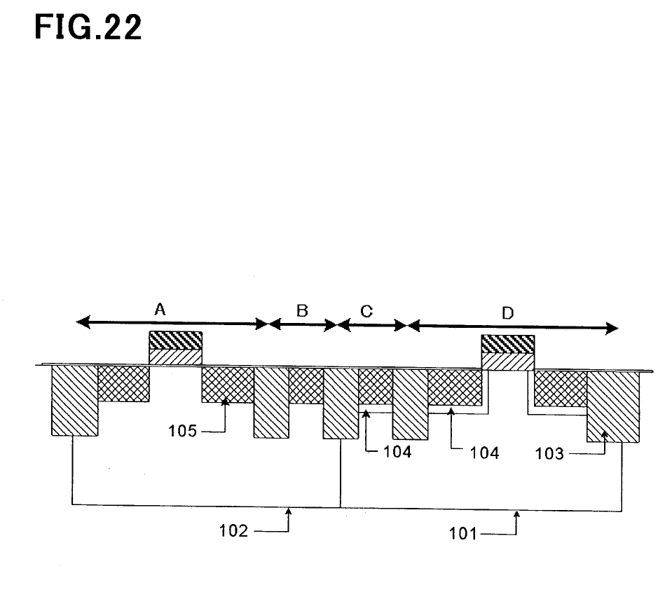

As illustrated in FIG. 22, the pocket boron regions 104 are formed in the P well diffusion layer region C and the NMOS transistor region D as a result of the implantation of boron. The pocket boron suppresses short channel effect of the NMOS transistor.

Though explained in detail later, pocket boron was implanted only into the NMOS transistor region D in a conventional semiconductor device. In contrast, pocket boron is implanted further into the P well diffusion layer region C in the CMOS transistor 100 in accordance with the first embodiment, and hence, the CMOS transistor 100 provides advantages explained later.

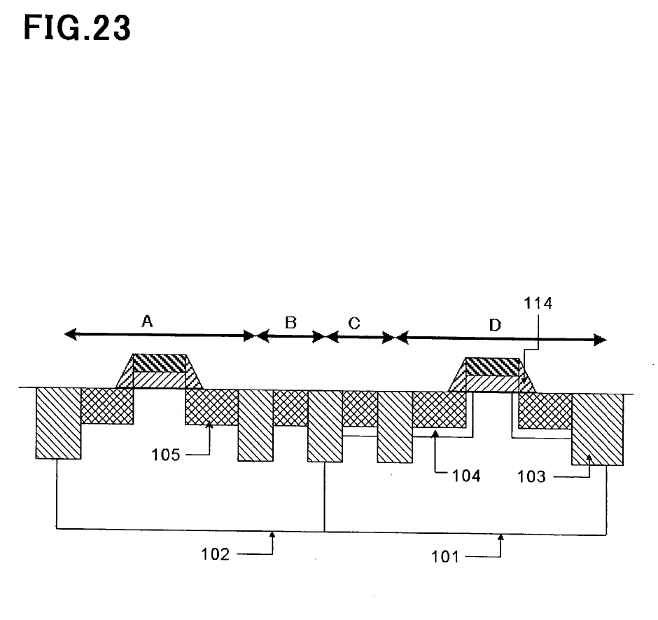

Then, a nitride film is formed over the silicon substrate by a thickness of 50 nm by LP-CVD. Then, anisotropic dry etching is carried out to the nitride film to thereby form the LDD sidewall 114 on sidewalls of an island-shaped multi-layered structure comprised of the gate polysilicon film 108 and the gate WSi film 109, as illustrated in FIG. 23.

Then, a resist pattern is formed on the silicon substrate by means of photolithography. The resist pattern has an opening through which the PMOS transistor region A and the P well diffusion layer region C are exposed. Then, SD boron is implanted into the silicon substrate with the resist pattern being used as a mask. For instance, the silicon substrate is implanted at 25 keV with doses of 3×10¹⁵ cm³ of SD boron.

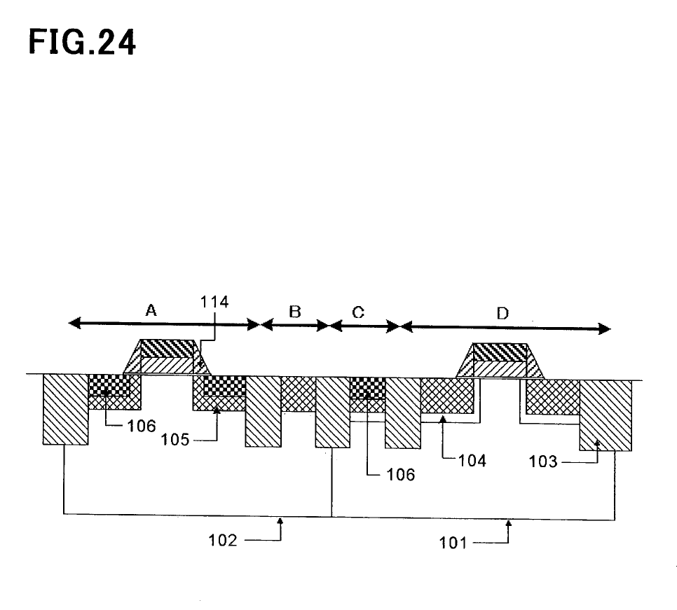

As illustrated in FIG. 24, the source and drain regions 106 of the PMOS transistor are formed in the PMOS transistor region A and the P well diffusion layer 106 is formed in the P well diffusion layer region C as a result of the SD boron implantation.

Then, a resist pattern is formed on the silicon substrate by means of photolithography. The resist pattern has an opening through which the N well diffusion layer region B and the NMOS transistor region D are exposed. Then, SD arsenic is implanted into the silicon substrate with the resist pattern being used as a mask. For instance, the silicon substrate is implanted at 30 keV with doses of 3×10¹⁵ cm³ of SD arsenic.

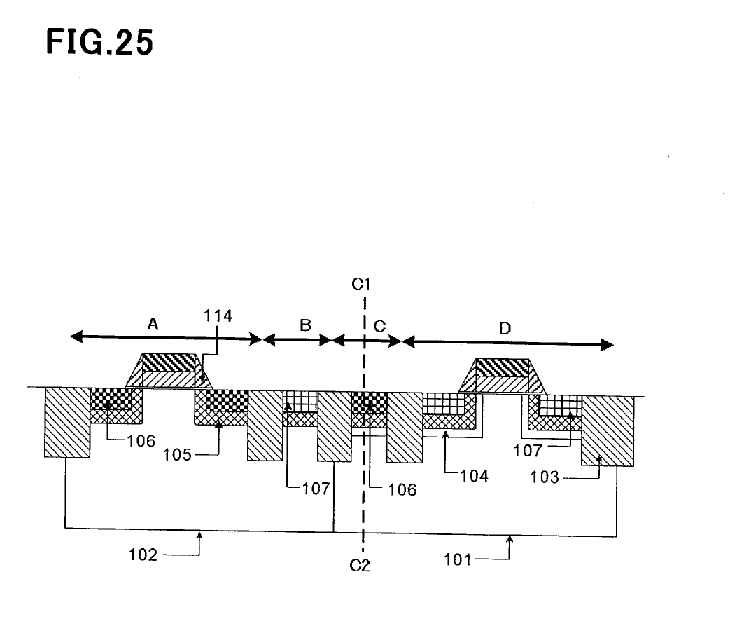

As illustrated in FIG. 25, the source and drain regions 107 of the NMOS transistor are formed in the NMOS transistor region D and the N well diffusion layer 107 is formed in the N well diffusion layer region B as a result of the SD arsenic implantation.

Then, the silicon substrate is subject to rapid thermal annealing (RTA) at 900 degrees centigrade for 10 seconds for activating ions of pocket boron contained in the pocket boron region 104, phosphorus contained in the LDD region 105, boron contained in the source and drain regions 106 and the P well diffusion layer 106, and arsenic contained in the source and drain regions 107 and the N well diffusion layer 107.

Then, as illustrated in FIG. 17, the interlayer insulating film 110 is formed entirely over the silicon substrate. Then, contact holes are formed throughout the interlayer insulating film 110 such that they reach the source and drain regions 106, the P well diffusion layer 106, the source and drain regions 107 and the N well diffusion layer 107.

Then, the contact holes are filled with metal such as copper to thereby fabricate the contact plugs 113.

Then, on the interlayer insulating film 110 are formed the wiring layers 111 in electrical contact with the contact plugs 113.

Thus, there is completed the semiconductor integrated circuit illustrated in FIG. 17.

It should be noted that material of which parts constituting the CMOS transistor 100 are composed, a method of forming films, and figures are not to be limited to the above-mentioned ones.

In accordance with the first embodiment, the P well diffusion layer region C and the P well 101 can be electrically connected to each other without carrying out any additional steps.

FIG. 18 illustrates an impurity profile along the broken line C1-C2 in the P well diffusion layer region C, illustrated in FIG. 25. FIG. 18 illustrates a final profile of the implanted impurities (P well boron, LDD phosphorus, pocket boron, SD boron) having experienced thermal annealing.

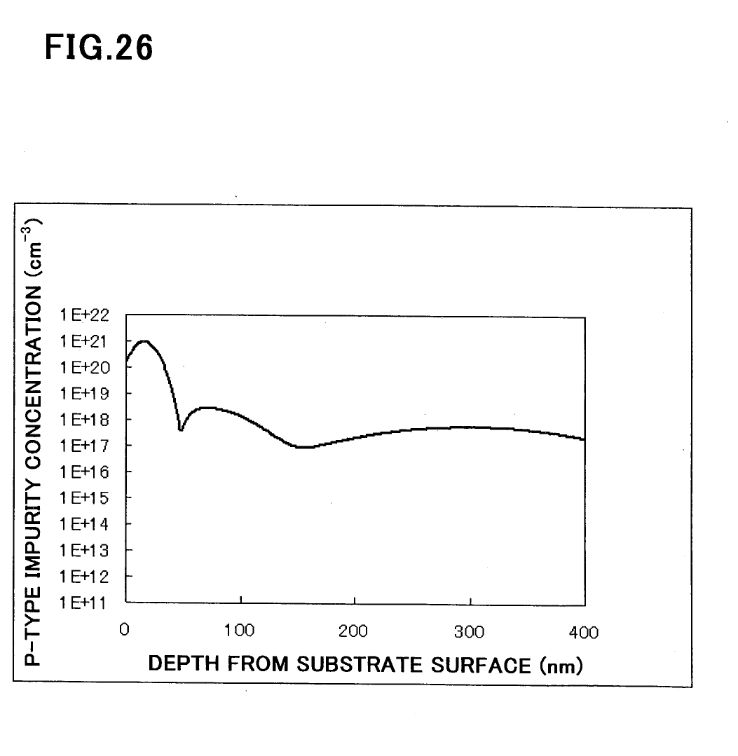

FIG. 26 is a graph showing a curve indicative of an amount of impurity calculated by subtracting a total amount of N-type impurity (LDD phosphorus) from a total amount of P-type impurities (P well boron, pocket boron and SD boron). The curve in FIG. 26 is based on FIG. 18.

As is understood in view of FIG. 26, a P-type region extends without any break, which means that the P well diffusion layer region C and the P well 101 are electrically connected to each other. Thus, it is possible to apply a voltage to the P well 101 through the P well diffusion layer region C from an external circuit, ensuring that the semiconductor integrated circuit in accordance with the first embodiment can stably operate.

[Second Embodiment]

The CMOS transistor 100 in accordance with the first embodiment is designed to include one PMOS transistor and one NMOS transistor. However, in actual use of a CMOS transistor, MOS transistors having different source and drain in structure from one another are frequently used. For instance, a first MOS transistor is used between a memory and a logic, and a second MOS transistor having source and drain which are different in structure from those of the first MOS transistor is used between an external power source and an internal voltage converter. A semiconductor device in accordance with the second embodiment is designed to include one PMOS transistor and two NMOS transistors.

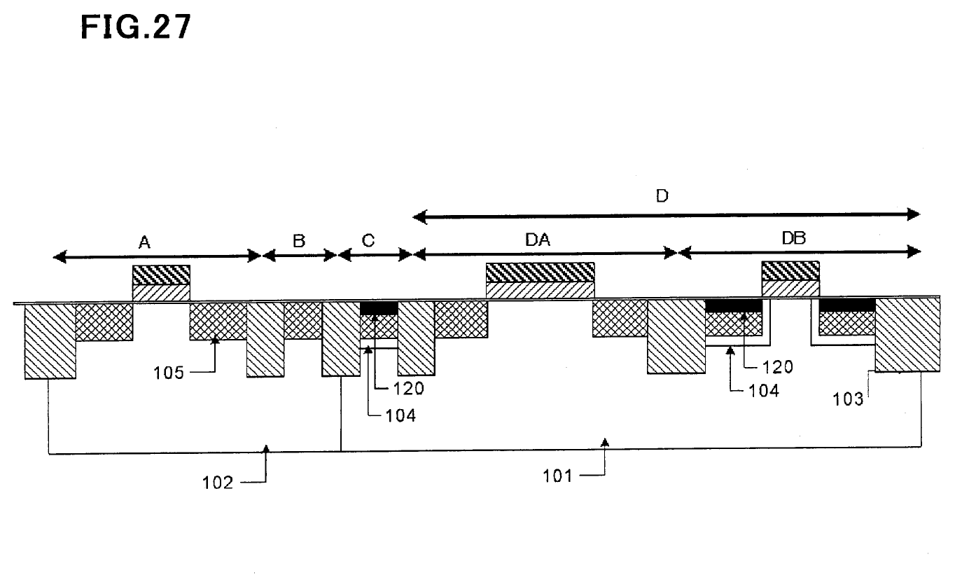

As illustrated in FIG. 27, the NMOS transistor region D in the second embodiment is comprised of a high-voltage NMOS region DA and a low-voltage NMOS region DB. For instance, the PMOS transistor fabricated in the PMOS transistor region A and a low-voltage NMOS transistor fabricated in the low-voltage NMOS region DB have a gate electrode length of 0.20 micrometers, and a high-voltage NMOS transistor in the high-voltage NMOS region DA has a gate electrode length of 0.40 micrometers.

First, the steps having been explained with reference to FIGS. 19 to 21 in the first embodiment are carried out. As a result, there is fabricated a silicon substrate having such a cross-section as illustrated in FIG. 21.

Then, a resist pattern is formed on the silicon substrate by means of photolithography. The resist pattern has an opening through which the P well diffusion layer region C and the low-voltage NMOS region DB are exposed. Then, pocket boron and arsenic is implanted into the silicon substrate with the resist pattern being used as a mask. Thus, as illustrated in FIG. 27, there are formed a pocket boron region 104 and a LDD arsenic region 120 in the low-voltage NMOS transistor fabricated in the low-voltage NMOS region DB.

For instance, the silicon substrate may be implanted at 20 keV with doses of 2×10¹³ cm⁻² of pocket boron, and at 20 keV with doses of 1×10¹⁴ cm⁻² of arsenic.

In the high-voltage NMOS transistor fabricated in the high-voltage NMOS region DA, it is necessary to relax an electric field at a boundary between a channel and a drain in order to prevent reduction in a resistance to hot carriers. Hence, it is preferable not to implant pocket boron into the silicon substrate. In contrast, it is necessary to implant pocket boron into the silicon substrate in the low-voltage NMOS transistor fabricated in the low-voltage NMOS region DB in order to suppress short channel effect.

The implantation of arsenic by which the LDD arsenic region 120 is formed reduces a resistance of a LDD region in the low-voltage NMOS transistor fabricated in the low-voltage NMOS region DB.

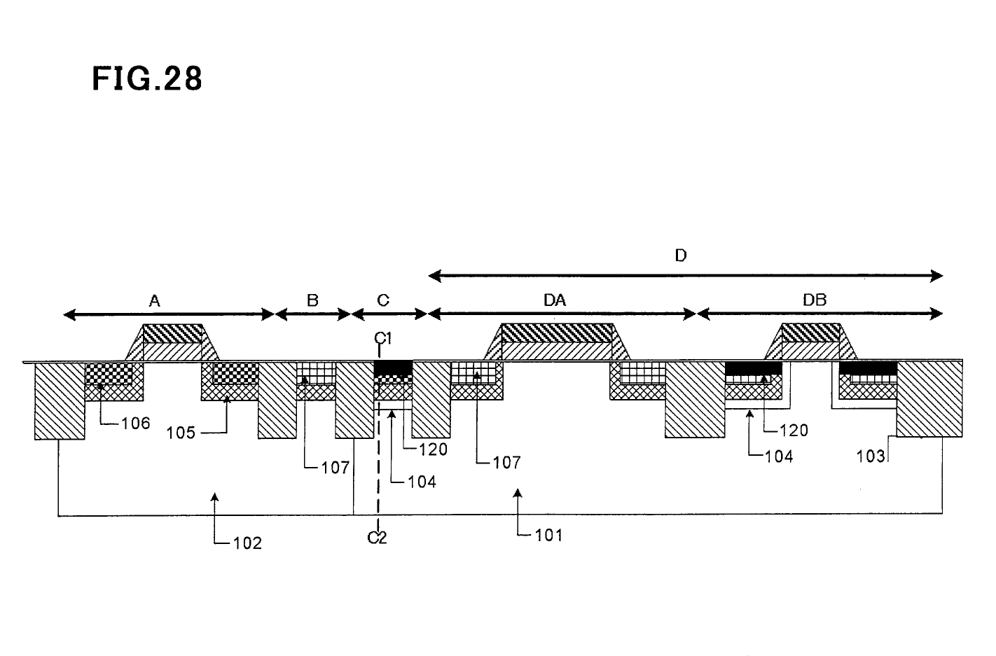

Thereafter, the steps having been explained with reference to FIGS. 23 to 25 in the first embodiment are carried out. As a result, the semiconductor device having such a cross-section as illustrated in FIG. 28 is fabricated.

Similarly to the first embodiment, it should be noted that material of which parts constituting the semiconductor device in accordance with the second embodiment are composed, a method of forming films, and figures are not to be limited to the above-mentioned ones.

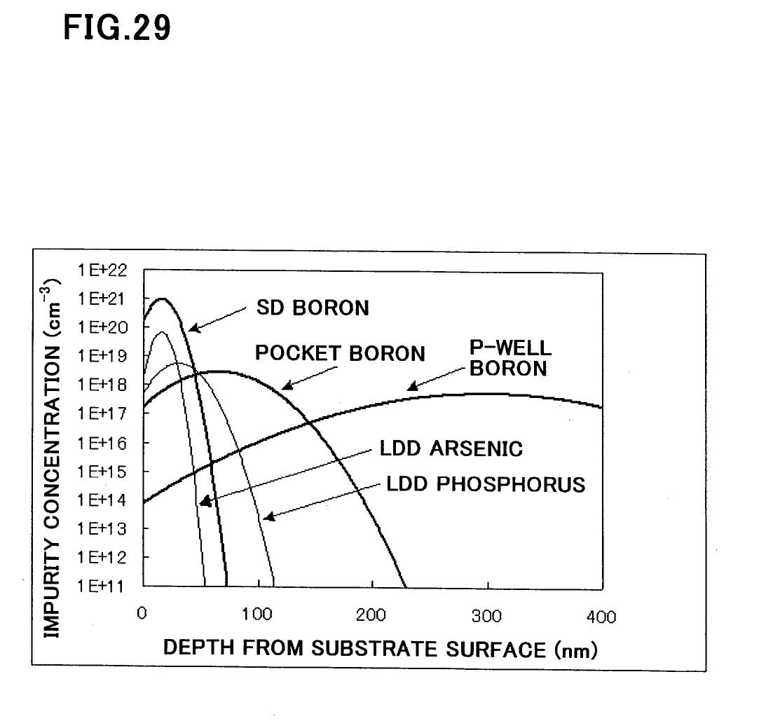

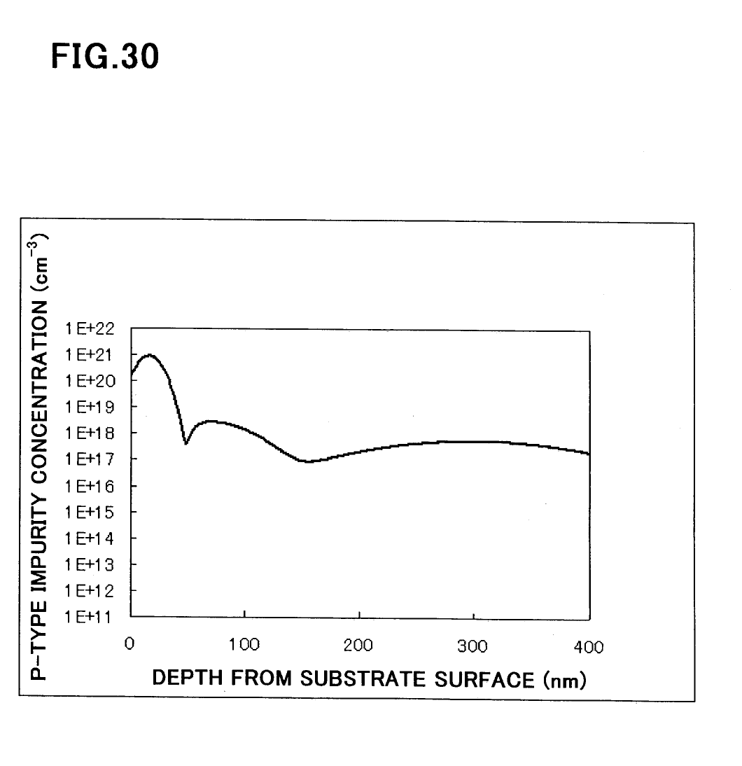

FIG. 29 illustrates an impurity profile along the broken line C1-C2 in the P well diffusion layer region C illustrated in FIG. 28. FIG. 30 is a graph showing a relation between an amount of impurity defined by subtracting a total amount of N-type impurity (LDD phosphorus and LDD arsenic) from a total amount of P-type impurity (P well boron, pocket boron and SD boron), and a depth measured from a surface of a silicon substrate.

As is understood in view of FIG. 30, a P-type region extends without any break, which means that the P well diffusion layer region C and the P well 101 are electrically connected to each other.

The second embodiment is different from the first embodiment in that arsenic as N-type impurity as well as pocket boron as P-type impurity is implanted into a silicon substrate in the P well diffusion layer region C to form the pocket boron region 104 and the LDD arsenic region 120. Even if N-type impurity is implanted into a silicon substrate, it is possible to electrically connect the P well diffusion layer region C and the P well 101 to each other, because P-type impurity having been implanted into a silicon substrate concurrently with the N-type impurity works well. As a result, similarly to the first embodiment, it is possible to apply a voltage to the P well 101 through the P well diffusion layer region C from an external voltage source to thereby ensure stable operation of the semiconductor device.

[Third Embodiment]

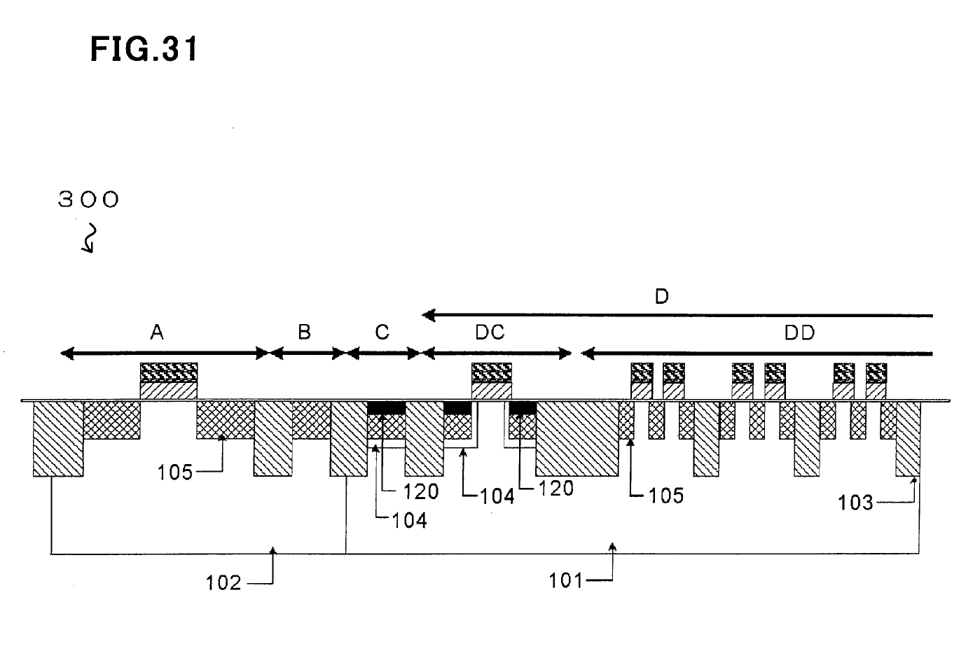

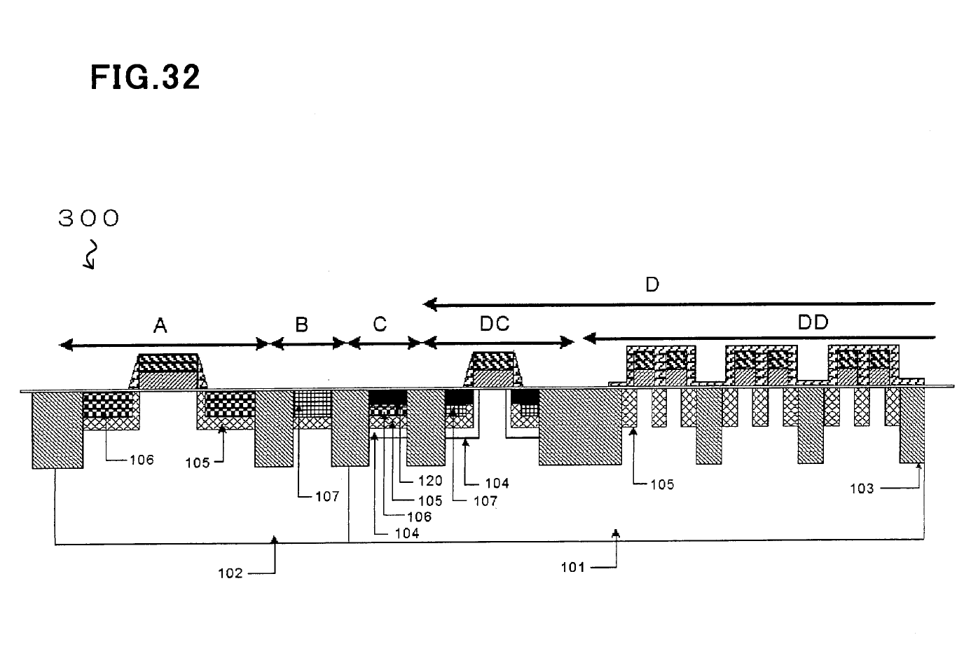

FIGS. 31 and 32 are cross-sectional views of a semiconductor device in accordance with the third embodiment of the present invention.

Hereinbelow is explained the semiconductor device in accordance with the third embodiment, with reference to FIGS. 31 and 32. The semiconductor device in accordance with the third embodiment is fabricated as a DRAM integrated circuit.

A CMOS transistor 300 in accordance with the third embodiment is designed to include one PMOS transistor and two NMOS transistors.

The CMOS transistor 300 in accordance with the third embodiment has four regions, specifically, a PMOS transistor region A in which a PMOS transistor is fabricated, an N well diffusion layer region B through which a voltage is applied to an N well, a P well diffusion layer region C through which a voltage is applied to a P well, and an NMOS transistor region D in which an NMOS transistor is fabricated. The NMOS transistor region D is comprised of a peripheral transistor region DC in which a peripheral transistor is fabricated, and a cell transistor region DD in which a cell transistor is fabricated.

For instance, the PMOS and NMOS transistors have a gate length of 0.2 micrometers, and the cell transistor has a gate length of 0.12 micrometers.

First, the steps having been explained with reference to FIGS. 19 to 21 in the first embodiment are carried out. As a result, there is fabricated a silicon substrate having such a cross-section as illustrated in FIG. 21.

Then, a resist pattern is formed on the silicon substrate by means of photolithography. The resist pattern has an opening through which the P well diffusion layer region C and the peripheral transistor region DC are exposed. Then, pocket boron and arsenic is implanted into the silicon substrate with the resist pattern being used as a mask. Thus, as illustrated in FIG. 31, there are formed a pocket boron region 104 and a LDD arsenic region 120 in the NMOS transistor fabricated in the peripheral transistor region DC.

For instance, the silicon substrate may be implanted at 20 keV with doses of 2×10¹³ cm⁻² of pocket boron, and at 20 keV with doses of 1×10¹⁴ cm⁻² of arsenic.

It is important in the cell transistor to be fabricated in the cell transistor region DD to reduce leakage out of a drain diffusion layer in view of holding characteristic of DRAM. To this end, it is necessary to relax an electric field at a boundary between a channel or a well and a drain, and accordingly, it is preferable not to implant pocket boron into the silicon substrate.

It is also preferable not to implant LDD arsenic into the silicon substrate in order to prevent an increase in leakage caused by implantation defect.

In contrast, it is not so important in the NMOS transistor to be fabricated in the peripheral transistor region DC to reduce junction leakage in comparison with a cell transistor to be fabricated in the cell transistor region DD. Hence, it is preferable to implant pocket boron and LDD arsenic into the silicon substrate in order to suppress short channel effect and lower a resistance of a LDD region.

Thereafter, the steps having been explained with reference to FIGS. 23 to 25 in the first embodiment are carried out. As a result, the semiconductor device having such a cross-section as illustrated in FIG. 32 is fabricated.

A sidewall is not etched back in the cell transistor region DD in order to prevent deterioration of holding characteristic of DRAM. In addition, SD arsenic is not implanted into the silicon substrate in order to prevent the semiconductor device from being damaged due to etching and/or implantation.

Thereafter, though not illustrated, steps of forming a bit line, forming a capacity and forming a wiring layer are carried out. Thus, the DRAM integrated circuit in accordance with the third embodiment is completed.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 2002-156605 filed on May 30, 2002 including specification, claims, drawings and summary is incorporated herein by reference in its entirety.

What is claimed is:

1. A semiconductor device including a PMOS transistor region in which a PMOS transistor is fabricated, an N well diffusion layer region in which an N well diffusion layer is fabricated, a P well diffusion layer region in which a P well diffusion layer is fabricated, and an NMOS transistor region in which an NMOS transistor is fabricated,
wherein each of said NMOS transistor region and said P well diffusion layer region includes a P-type impurity region in which a P-type impurity is implanted, and
a P well is formed across said P well diffusion layer region and said NMOS transistor region such that said P well is electrically connected to said P well diffusion layer region.

2. The semiconductor device as set forth in claim 1, wherein said P-type impurity is pocket boron.

3. The semiconductor device as set forth in claim 1, wherein said semiconductor device includes a plurality of NMOS transistor regions in each of which an NMOS transistor is fabricated.

4. The semiconductor device as set forth in claim 3, wherein NMOS transistors to be fabricated in said NMOS transistor regions have source and drains structurally different from one another.

5. The semiconductor device as set forth in claim 1, wherein said semiconductor device includes two NMOS transistor regions in which low-voltage and high-voltage NMOS transistors are fabricated.

6. The semiconductor device as set forth in claim 1, wherein said NMOS transistor region is comprised of a first region in which a peripheral transistor is fabricated and a second region in which a cell transistor is fabricated.

7. A method of fabricating a semiconductor device including a PMOS transistor region in which a PMOS transistor is fabricated, an N well diffusion layer region in which an N well diffusion layer is fabricated, a P well diffusion layer region in which a P well diffusion layer is fabricated, and at least one NMOS transistor region in which an NMOS transistor is fabricated,
said method including the steps of:
(a) implanting N-type impurity into a substrate to concurrently form a lightly doped drain (LDD) region of said NMOS transistor and a pocket region of said PMOS transistor area; and
(b) implanting a P-type impurity into said NMOS transistor region and said P well diffusion layer region to electrically connect a P well formed across said P well diffusion layer region and said NMOS transistor region, to said P well diffusion layer region.

8. The method as set forth in claim 7, wherein said P-type impurity is pocket boron.

9. The method as set forth in claim 7, wherein an N-type impurity as well as said P-type impurity is implanted into said P well diffusion layer region in said step (b) to form a LDD region.

10. The method as set forth in claim 9, wherein said N-type impurity is arsenic.
